(19) United States
(12) Patent Application Publication
(10) Pub. No.: US 2010/0171543 A1
(43) Pub. Date: Jul. 8, 2010

(54) PACKAGED POWER SWITCHING DEVICE

(75) Inventors: Jacek Korec, Sunrise, FL (US); Christopher F. Bull, Center Valley, PA (US); Juan Alejandro Herbsommer, Schnecksville, PA (US); David Jauregui, Bethlehem, PA (US); Christopher B. Kocon, Mountaintop, PA (US)

Correspondence Address: TEXAS INSTRUMENTS INCORPORATED, P O BOX 655474, M/S 3999, DALLAS, TX, 75265, US

(73) Assignee: Ciclon Semiconductor Device Corp., Bethlehem, PA (US)

(21) Appl. No.: 12/350,651

(22) Filed: Jan. 8, 2009

(51) Int. Cl. H03K 17/687; H01L 29/94; H01L 23/495

(52) U.S. Cl. 327/436; 257/335; 257/666; 257/E29.345; 257/E23.01

(57) ABSTRACT

A packaged switching device for power applications includes at least one pair of power MOSFET transistor dies connected between upper and lower power source rail leads, a high side one of the pair of MOSFET transistor dies being connected to the upper power source rail lead and a low side one of the pair of MOSFET transistor dies being connected to the lower power source rail lead. At least one of the MOSFET transistor dies is configured for vertical current flow therethrough and has a source electrode at a backside thereof.

### FIELD OF THE INVENTION

The present invention relates to semiconductor devices and more particularly to power MOSFET devices.

### BACKGROUND OF THE INVENTION

Power switching devices connected in pairs in a totem pole fashion between the upper and lower rails of the power source are common in power electronics applications as described in, for example, U.S. Pat. No. 6,246,296 to Smith, the entirety of which is hereby incorporated by reference herein. As shown in FIG. 1 of Smith (reprinted as FIG. 1 of this application) for the case of two insulated-gate bipolar transistor (IGBT) devices, one switch is connected between the supply voltage and the load connector and the second switch is connected between the load connector and ground. The totem pole configuration of the switches is a basic element of the majority of Pulse Width Modulation (PWM) systems like Switched Mode Power Supply (SMPS) or motor control schemes.

The same configuration of two power switches implemented in a converter circuit is usually called a push-pull stage, as described in U.S. Pat. No. 4,633,106 to Backes et al. and U.S. Pat. No. 5,515,258 to Viertler, the entirety of each of which is hereby incorporated by reference herein. An example from Viertler reprinted as FIG. 2 in this application uses bipolar transistors as power switches. Voltage regulators, such as DC-to-DC converters, are used to provide stable voltage sources for electronic systems. Efficient DC-to-DC converters are particularly needed for battery management in low power devices, such as laptop notebooks and cellular phones. Switching voltage regulators (or simply “switching regulators”) are known to be an efficient type of DC-to-DC converter. A switching regulator generates an output voltage by converting an input DC voltage into a high frequency voltage, and filtering the high frequency input voltage to generate the output DC voltage. Specifically, the switching regulator includes a switch for alternately coupling and decoupling an input DC voltage source, such as a battery, to a load, such as an integrated circuit. An output filter, typically including an inductor and a capacitor, is coupled between the input voltage source and the load to filter the output of the switch and thus provide the output DC voltage. A controller, such as a pulse width modulator or a pulse frequency modulator, controls the switch to maintain a substantially constant output DC voltage.

A more recent example of a SMPS circuit is a synchronous buck converter as presented by Jon Mark Hancock at the Intel Technology Symposium in 2003 (“The future of discrete power in VRM solutions: LV device roles and silicon/package technology to meet upcoming mainstream power delivery requirements”) (hereinafter, the “ITS'2003 Presentation”). Two power MOSFET switches are connected in a push-pull configuration as shown in FIG. 3. The MOSFET Q1 connected between the supply voltage (Vᵢₙ) and the LC output filter is called the high side switch or control FET. The second device, MOSFET Q2, connected between the LC output filter and ground is called the low side switch or sync FET, as it works as a synchronous rectifier substituting for a free wheeling diode. The common node between the high side and the low side switches is called a switched node.

As explained by J. Hancock in his ITS'2003 Presentation, parasitic inductances introduced by the assembly of the push-pull stage have a detrimental impact on the performance of the converter. Specifically, the total inductance in the main current path from Vᵢₙ to ground (inductance nos. 3, 8, 9 and 10 in FIG. 3) determines the voltage ringing on the switched node and the resulting power loss.

In a conventional approach, the two power switches Q1 and Q2 and the corresponding driver shown in FIG. 3 are integrated into a power module as shown in FIG. 4, as described in a presentation by Dr. P. Rutter at the 2004 Intel Technology Symposium (“Design Challenges of Integrated Power Trains (DrMOS)”) (hereinafter “ITS'2004 Presentation). In the power modules shown in FIG. 4, the wired connections between the switches (labeled 6.5 mΩ and 2 mΩ) as well as wired connections to the output terminals introduce significant inductance into the power circuit.

A more advanced module assembly reprinted in FIG. 5 is disclosed in Hashimoto et al., “Advanced Power SiP with Wireless Bonding for Voltage Regulators” July 2007, IEEE. In this module assembly, copper plates substitute for the connecting wires. These copper plates are wide and introduce minimum parasitic inductance. However, when used with power MOSFET devices with vertical current flow, e.g., devices such as planar DMOS (Double Diffused) and trench devices where the top metal is the source and the backside contact is the drain of the transistor, there is a need to connect the front metal on the high side switch (source) to the lead frame of the low side FET (drain). This approach consumes some area and increases the footprint of the module.

One possible solution to this problem is the use of lateral FETs (LDMOS), such as disclosed in U.S. Pat. No. 5,907,173 to Kwon et al., the entirety of which is hereby incorporated by reference herein, and shown in FIG. 6. LDMOS transistors can be integrated monolithically in a single power IC chip as proposed by U.S. Pat. No. 7,038,274 to You et al., the entirety of which is hereby incorporated by reference herein. As described by You et al., and shown in FIG. 8 reprinted therefrom, You et al. integrates the controller, driver transistor and switches on the same piece of silicon into a single IC. However, monolithic power IC implementation is very expensive and complicated, making this approach prohibitive for most power electronics applications.

A configuration for power switches is desired that does not introduce significant parasitic inductance, has minimum footprint area and low manufacturing cost.

### SUMMARY OF THE INVENTION

A packaged switching device for power applications includes at least one pair of power MOSFET transistor dies connected between upper and lower power source rail leads, a high side one of the pair of MOSFET transistor dies being connected to the upper power source rail lead and a low side one of the pair of MOSFET transistor dies being connected to the lower power source rail lead. At least one of the MOSFET transistor dies is configured for vertical current flow therethrough and has a source electrode at a backside thereof.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a circuit diagram of a prior art power switching device;

FIG. 2 is a circuit diagram of prior art power converter;

FIG. 3 is an illustration of a prior art power converter illustrating various parasitic inductances;

FIG. 4 illustrates a prior art integrated power module;

FIG. 5 illustrates another prior art voltage regulator;

FIG. 6 illustrates a prior art LDMOS transistor;

FIG. 7 illustrates another prior art regulator;

FIGS. 8 and 9 illustrate n-channel and p-channel LDMOS transistors with vertical current flow, respectively;

FIG. 10 illustrates an embodiment according to the present invention of a voltage regulator having a packaged switching device having n-channel high side and low side transistor devices;

FIGS. 11 and 11A illustrate an embodiment of the packaged switching device of FIG. 10;

FIGS. 12 and 12A illustrate an alternative embodiment of the packaged switching device of FIG. 10;

FIGS. 13 and 13A illustrate another alternative embodiment of the packaged switching device of FIG. 10;

FIG. 14 illustrates an embodiment according to the present invention of a voltage regulator having a packaged switching device having a p-channel high side transistor device and an n-channel low side transistor device;

FIG. 15 illustrates an embodiment of the packaged switching device of FIG. 14; and

FIGS. 16 and 16A illustrate and alternative embodiment of the packaged switching device of FIG. 14.

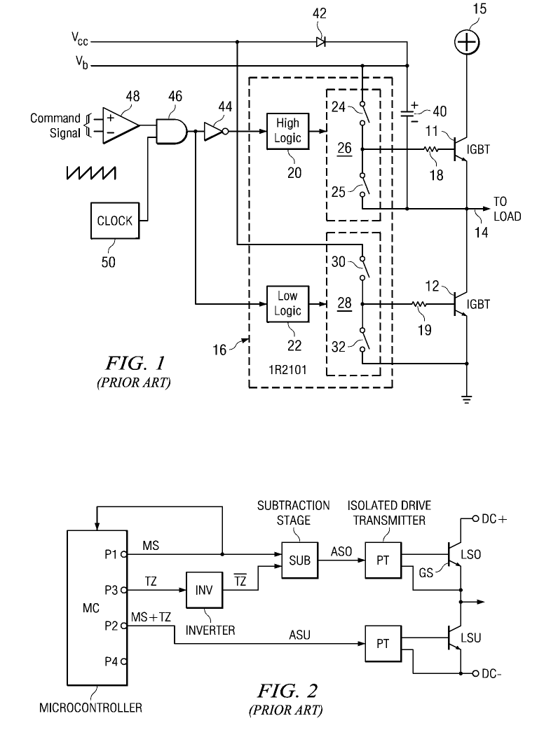

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

In embodiments of an exemplary packaged power switching device described herein, two power MOSFET transistors are connected in a totem pole or push-pull (used interchangeably herein) fashion where at least one of them has a device structure with a vertical current flow and a source electrode at the backside of the die. This setup allows for two device terminals at the switched output node to be placed in intimate contact or, alternatively, to connect the front metallization electrodes with a wide connector (e.g., clip or strap) that introduces minimal parasitic inductance.

Examples of preferred power MOSFET devices that may be used in the packaged power switch device with vertical current flow and backside source electrode/terminal are described in the commonly assigned U.S. Pat. No. 7,235,845 to Xu et al. entitled “Power LDMOS transistor,” the entirety of which is hereby incorporated by reference herein. LDMOS transistors as disclosed in Xu et al. are preferred for switching regulators because of their performance in terms of a tradeoff between their specific on-resistance (R_{dson}) and drain-to-source breakdown voltage (BV_{ds}). Although LDMOS devices are preferred for devices having vertical current flow, in embodiments, one or more of the devices may be, for example, a DMOS device or a trench device.

FIG. 8, reprinted from Xu et al., illustrates an n-channel LDMOS transistor device with backside source electrode. More specifically, the transistor 100 includes a substrate 112, which is preferably a silicon wafer substrate highly doped with P-type dopants, such as boron, and having P+ (or P++) dopant concentration. A source electrode 160 comprising a conductive material such as Ti/Ni/Ag is coupled to the bottom surface of the substrate 112. The source electrode preferably comprises a planar electrode extending over the entire bottom surface of the die substrate 110. The substrate 112 has a thickness of less than 200 μm, and preferably less than about 100 μm (about 3-4 mils), and most preferably equal to about 50 μm (2 mils), thereby minimizing the contribution of the substrate to the on-resistance of the transistor.

An epitaxial layer 214 is formed over the substrate 112 and has an upper surface 116. The epitaxial layer 214 can have dopants of N (arsenic or phosphorous) or P (boron) dopant type and a dopant concentration of N− or P−. The epitaxial layer 214 preferably has a thickness between about 2 to 4 μm including the transition region of the dopant concentration gradient. The epitaxial layer 214 includes a buffer region 202 formed between the substrate 112 and the body region 232 and lightly doped drain region 226. The buffer region 202 comprises a layer of silicon doped with p-dopants at a concentration equal to or greater than the dopant concentration of the body region 232. The buffer layer 202 abuts the sidewalls of source contact layer 150 and is preferably formed to a thickness between about 0.3 to 0.6 μm. The buffer layer 202 may be formed by deep implantation of Boron into the epitaxial layer 214 before the formation of the gate 118. The buffer layer 202 serves to suppress the well-documented short channel effects by helping to ensure that the depletion region does not reach too far into the channel. The buffer layer provides for better control and reproducibility of the breakdown voltage of the transistor. The breakdown is limited between the drain contact region 128 and the buffer layer 202, rather than between the drain contact region 128 and the upper surface of the substrate 112

A conductive gate 118 overlies the upper surface 116 of the epitaxial layer 214. The conductive gate 118 comprises a lower doped polysilicon layer 120 with an upper silicide layer 122 formed therein or thereover. Silicide layer 122 can comprise any transition metal silicide selected from the group consisting of Ti, W and Co silicides. The conductive gate 118 is formed over a gate dielectric 124.

Drain implant region 128, having dopant concentration N+, is formed in epitaxial layer 214. Lightly doped drain region 126 is formed completely within epitaxial layer 214 and forms an enhanced drift region. The lightly doped drain region 226 forms a PN junction with the layer 202. The LDMOS structure 100 also includes a source implant region 130 having a conductivity N+ spaced from the enhanced drift region 226 and a body region 232 having P-type dopants and having a conductivity of P concentration, which has a subregion between the source 130 and enhanced drain region 226, forming a channel region therebetween.

The transistor device 100 includes an insulating layer 138 formed over the source implant region 130, over the sidewalls of the conductive gate 118 (forming side spacers) and its upper surface, as well as over the enhanced drain drift region 226 and drain implant region 128. The insulating layer 138 insulates the drain and gate regions from the source contact layer described below.

A deep trench 140 is etched adjacent to and contacting the source implant region 130 and body region 132. The trench 140 is preferably formed entirely through the epitaxial layer 214 and, optionally, partially into the substrate layer 112. A highly doped contact implant region 136 is then formed in the substrate 112 having a concentration P++. A conductive layer 150 is formed by a CVD deposition of a silicide, which is subsequently patterned to form the shield electrode 154. The continuous layer 150 forms a source contact, a gate shield and a field plate for the LDMOS transistor 100. The source contact that shorts the source implant region 130, body region 232, buffer layer 202 and highly doped contact region 136. The continuous layer 150 extends over insulation layer 138, over gate 118 and the sidewall spacers of the gate 118 to form a gate shield 154, which shields the gate 118 and source 130 from the drain electrode. Still further, the continuous layer 150 extends over a portion of the insulation layer 138 that is formed over lightly doped region 126 to form a field plate portion 152. The trench 140 is filled with an insulating material during the deposition of the insulating layer 144 over which the drain electrode/terminal 148 is formed.

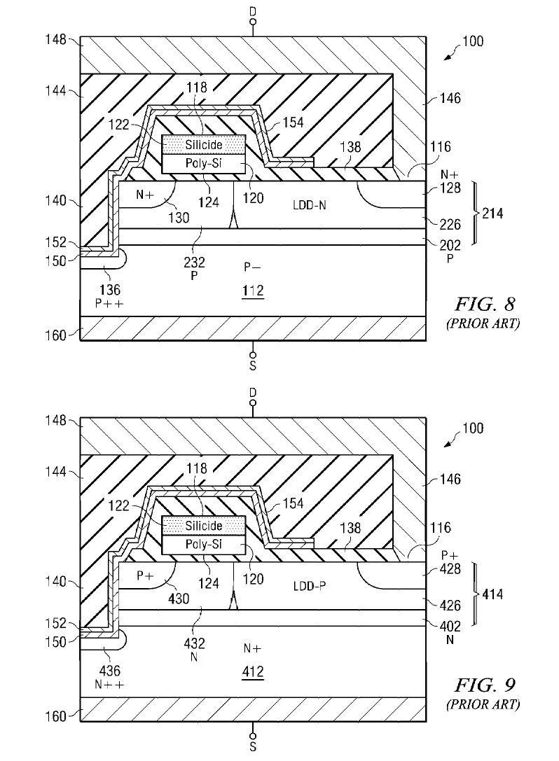

FIG. 9 illustrates a p-channel LDMOS device reprinted from Xu et al. The device is identical to the n-channel LDMOS transistor of FIG. 8 except for dopant types for epitaxial layer 414, substrate 412, drain 428, source 430, body 432, drain extension 426, implant layer 402 and implant region 436.

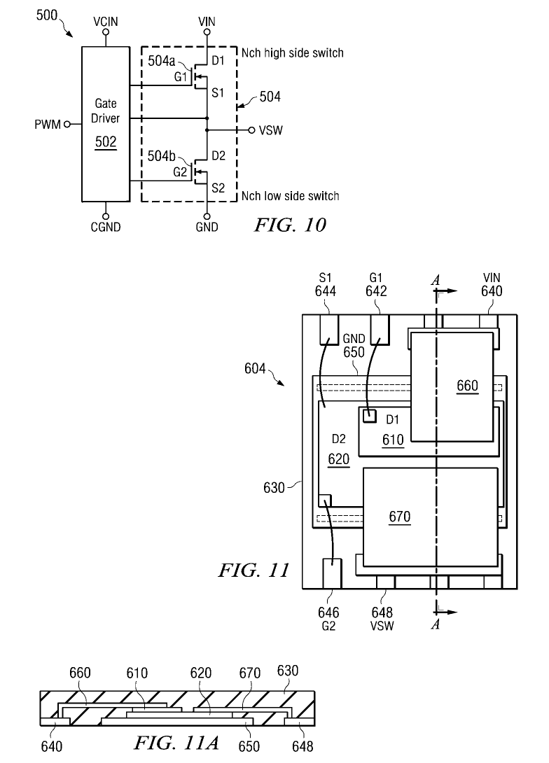

FIG. 10 illustrates an embodiment of a portion of a power converter device 500. The device 500 includes a gate driver 502 and an pair of power transistors 504 arranged in a totem pole configuration (also known as a push-pull configuration) having a high side device 504a and a low side device 504b. In this illustrated embodiment, both devices 504a, 504b are n-channel devices. This totem pole configuration requires the drain D1 of the high side switch to be connected to the upper supply voltage node (VIN), the source S1 of the high side switch and the drain D2 of the low side switch to be connected together at the switched output node (VSW), and the source S2 of the low side switch to be connected to the lower supply voltage node (GND). The gates G1 and G2 are biased by the gate driver circuit 502 responsive to a pulse width modulation signal PWM.

Details of the gate driver circuit 502, which drives the switching device 504 in power conversion applications are familiar to those in the art and are not detailed herein. One example of a voltage regulator having driver and control circuitry is shown in, for example, FIG. 7 (reprinted from You et al.). As shown in FIG. 7 and described in You et al, the switching regulator is coupled to a first high DC input voltage source, such as a battery, by an input terminal. The switching regulator is also coupled to a load, such as an integrated circuit, by an output terminal. The switching regulator serves as a DC-to-DC converter between the input terminal and the output terminal 408. The switching regulator includes a switching circuit that serves as a power switch for alternately coupling and decoupling the input terminal to an intermediate terminal. The switching circuit includes a rectifier coupling the intermediate terminal 412 to ground.

The intermediate terminal is coupled to the output terminal by an output filter. The output filter converts the rectangular waveform of the intermediate voltage at the intermediate terminal into a substantially DC output voltage at the output terminal. Specifically, in a buck-converter topology, the output filter includes an inductor connected between the intermediate terminal and the output terminal and a capacitor connected in parallel with the load. During a high side conduction period, the high side switch is closed, and the voltage source supplies energy to the load and the inductor through the high side switch. On the other hand, during a low side conduction period, the low side transistor switch is closed, and current flows through the low side transistor switch as energy is supplied by the inductor. The resulting output voltage is a substantially DC voltage.

The switching regulator includes a controller and a pair of drivers for controlling the operation of the switching circuit. The controller causes the switching circuit to alternate between the aforementioned high side and low side conduction periods to generate an intermediate voltage at the intermediate terminal that has a rectangular waveform. The controller can also include a feedback circuit, which measures the output voltage and the current passing through the output terminal. Although the controller is typically a pulse width modulator, other modulation schemes, such as pulse frequency modulation, can be used.

Although the switching regulator discussed above in connection with You et al. has a buck converter topology, the other voltage regulator topologies, such as a boost converter or a buck-boost converter, are also applicable.

Improvements to the switching circuit component of, for example, prior art voltage regulators are illustrated herein and discussed below with reference to FIGS. 11-16.

Devices 504a and 504b of switching device 504 are preferably mounted on a lead frame and arranged in a single packaged semiconductor device having a first die (or dies) for the high side transistor device 504a and a second die (or dies) for the low side transistor device 504b. As shown in FIGS. 11-13, use of at least one LDMOS device as described above configured with vertical current flow and having a backside source electrode/terminal facilitates formation of low inductance, high performance connections within the packaged device.

In the embodiment illustrated in FIG. 11, die 610 corresponds to the n-channel high side switching transistor 504a of FIG. 10 and die 620 corresponds to the n-channel low side switching transistor 504b of FIG. 10. These two dies 610, 620 are placed one on the top of the other to form a stacked die arrangement, coupled to a lead frame and packaged within packaging/molding material 630 (e.g., an epoxy molding material or any other suitable commercially available molding material) to form a packaged switching device. A cross-section taken along lines A-A of the packaged device 1104 is shown in FIG. 11A and illustrates this arrangement in more detail. In this embodiment, both the high side transistor die 610 and the low side transistor die 620 are configured as MOSFET devices with vertical current flow and backside source electrodes. An exemplary n-channel device of this configuration is shown in FIG. 8. As the source electrode is on the backside of each die 610, 620, the drain electrode and gate electrode are on the topside of each die. These drain electrodes are labeled D1 and D2 in FIG. 11. Because the dies 610, 620 are stacked, the source electrode S1 of the high side die 610 can be directly coupled to the drain electrode D2 of the low side die 620. These die surfaces are preferably coupled together with a layer of conductive solder paste. This intimate contact between the drain D2 and source S1 contributes negligible parasitic inductance. This common node (S1/D2) is coupled to the switched output lead 648 of the lead frame (labeled VSW) through a wide, highly conductive connector in the form of a copper clip 670 coupled between the output lead 648 and the upper surface of die 620 (corresponding to terminal/electrode D2). Solder can also be used to facilitate connection of connector 670 to the die 620. While this connection also exhibits negligible parasitic inductance, inductance at this connection is not critical to the devices power loss. However, this wide conductor 670 provides for good current handling capability.

The high voltage lead 640 (labeled VIN) is also coupled to the drain D1 of the die 610 by a wide, low inductance connector 660. Limiting inductance at this connection is important for device performance. The bottom surface of die 620 is mounted directly onto the ground lead portion 650 of the leadframe of the packaged device 604. Again, a layer conductive solder (not shown) can be used to facilitate this connection. This intimate connection between the source (S2) of the low side transistor and the ground lead 650 also contributes negligible parasitic inductance at an important connection.

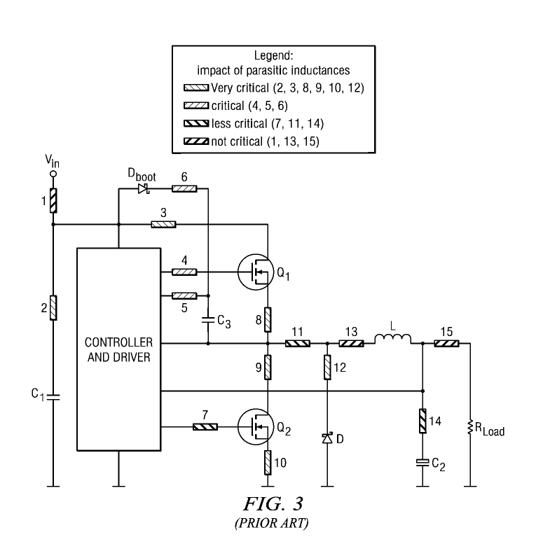

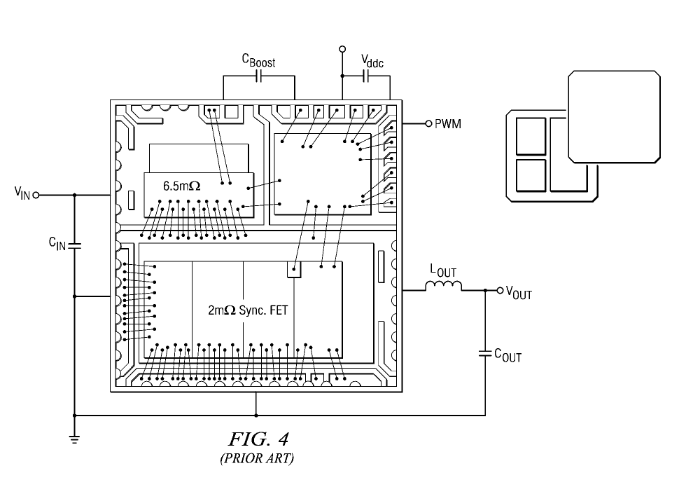

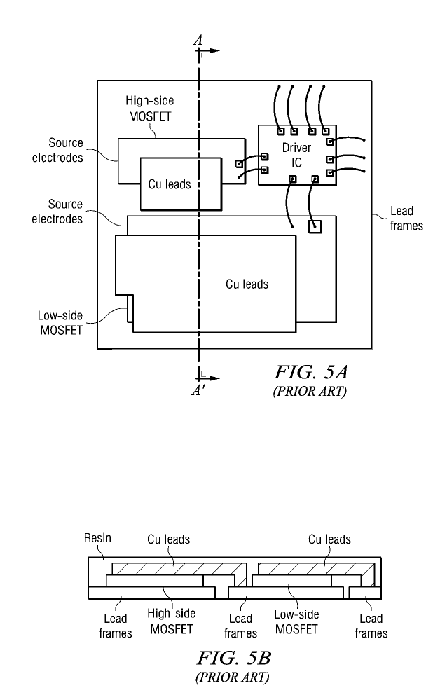

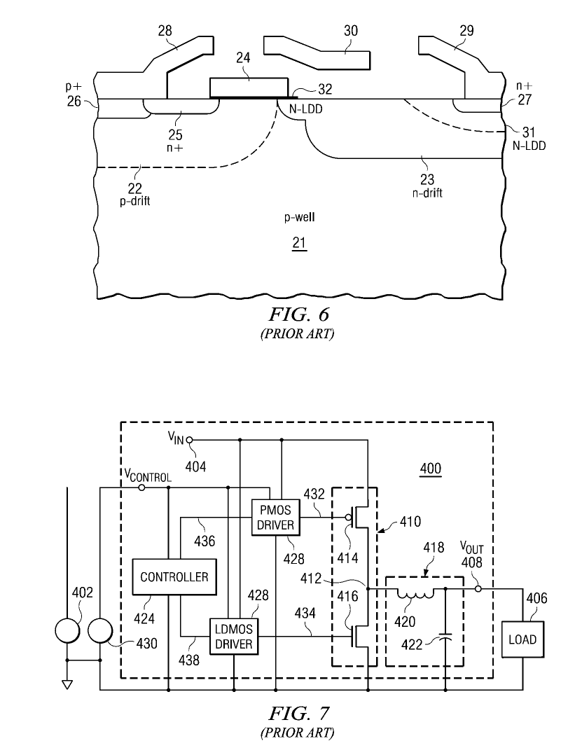

As also shown in the figures, the leadframe includes a gate lead portion 646 (labeled G2) for connections to the gate of the die 620, i.e., the gate of the low side transistor switch 504b. This connection is made with a wirebond as, with reference to FIG. 3, this connection is not a very critical source of parasitic inductance that affects device performance. Nonetheless, in embodiments, an appropriately sized gate clip could be used to make this connection. Similarly, a wirebond connects the gate of the die 610 to gate lead portion 642 (labeled G1) for making connections to the gate G1 of the high side transistor switch 504b. As will be apparent from comparing FIGS. 10 and 11, these gate lead portions 642, 646 are connected to a gate driver 502 in an assembled power converter device. This connection can be made through a printed circuit board, for example.

Finally, the packaged device includes a source lead portion 644 (labeled S1) that is wirebonded to the source S1 of the die 610 via its connection to the drain D2 of the die 620 (i.e., S1 and D2 are at the common switched output node). This lead 644 is used for coupling the source S1 to the gate driver 502 as shown in FIG. 10. As with the other wirebonds, the wirebond can be replaced with a conductive clip if parasitic inductance is a concern with the respective connection.

As discussed above, limiting parasitic inductances in the current path, i.e., between the high voltage rail and the high side switch, between the high side switch and the low side switch, and between the low side switch and low voltage rail, is important. Limiting parasitic inductance in this path reduces voltage ringing at the switched node and thus limits power losses. In the device of FIG. 11, the parasitic inductances at these connections are limited by the wide, low inductance connector 660 between the high voltage line (VIN) and the high side switch die 610, by the direct connection of the source of die 610 to the drain of die 620 and by the direct connection between the source of die 620 and the ground lead 650 (i.e., low voltage line). The gate electrodes of the FETs can be wired to the package terminals, as these inductance loops are outside of the main current path.

In embodiments, a Kelvin source terminal is used for the high side switch in order to decouple the gate drive circuit from the main current path. As known to the people skilled in the art, this allows for a more effective and fast switching of the high side device, which in turn improves the efficiency of the converter.

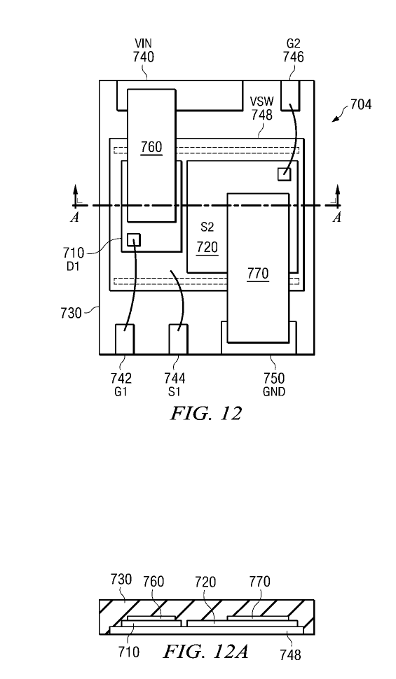

FIG. 12 illustrates an alternative embodiment of a packaged semiconductor device 704 having n-channel high side and low side switches with a low inductance current path. FIG. 12A is a cross-sectional view of the device 704 taken along line A-A. The leadframe of the device includes a high voltage line lead portion 740 (labeled VIN), lead portions 742, 746 for the gates of the switches (labeled G1 and G2, respectively), a lead portion 744 for the connection to the source S1 of the high side switch, a low voltage line lead portion 750 (labeled GND) and finally a central lead portion 748 on which dies 710 and 720 are mounted. The dies are packaged within packaging/molding material 703. Die 710 corresponds to high side switch 504a of FIG. 10 and is fabricated with its source S1 down (i.e., on the backside of the device) and its drain D1 up. As such, the source S1 of die 710 is coupled directly to the lead portion 748. The die 720 corresponds to low side switch 504b of FIG. 10 and, unlike die 710, is fabricated with its source S2 up and its drain D2 down (i.e., at the backside of the die). The source S1 and drain D2 are coupled together through the lead frame portion 748 (labeled VSW), which serves as the switched output node. This wide lead frame connector provides a low inductance connection between the source S1 and drain D2. Other important connections are also made by wide, low inductance connectors, including the connection from D1 to VIN lead portion 740 by connector 760 and the connection between source S2 and GND lead portion 750 by connector 770.

The embodiment shown in FIGS. 12 and 12A avoids the stacked die arrangement by utilizing a side-by-side placement of both transistor dies, while still providing for a low inductance current path in the packaged switching device. In this embodiment, only the high side switch requires a device structure with the source electrode at the backside of the die. This device has a larger footprint module than the stacked embodiment of FIGS. 11, 11A but reduced manufacturing complexity.

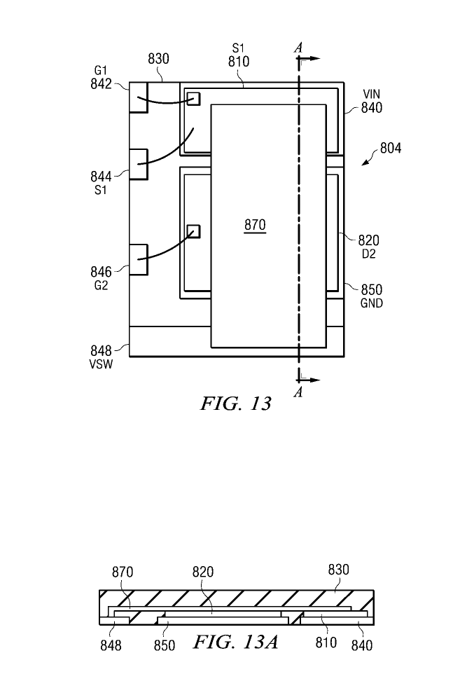

FIG. 13 illustrates an alternative embodiment of a packaged semiconductor device 804 having n-channel high side and low side switches with a low inductance current path packaged within packaging/molding material 803. FIG. 13A is a cross-sectional view of the device 804 taken along line A-A. The leadframe of the device includes a high voltage line lead portion 840 (labeled VIN), lead portions 842, 846 for the gates of the switches (labeled G1 and G2, respectively), a lead portion 844 for the connection to the source S1 of the high side switch, a low voltage line lead portion 850 (labeled GND) on which low side switch die 820 is mounted and a lead portion 848 (labeled VIN) on which high side switch die 810 is mounted.

Die 810 corresponds to high side switch 504a of FIG. 10 and is fabricated with its drain D1 down (i.e., on the backside of the device) and its source S1 up. As such, the drain D1 of die 810 is coupled directly to the lead portion 840 for the high voltage VIN. The die 820 corresponds to low side switch 504b of FIG. 10 and, unlike die 810, is fabricated with its drain D2 up and its source D1 down (i.e., at the backside of the die). The source S1 and drain D2 are coupled together through the wide, low inductance conductor 870. Conductor 870 connects these terminal to lead frame portion 848 (labeled VSW), which serves as the output node. This wide lead frame connector provides a low inductance connection between the source S1 and drain D2.

As can be seen from the figures, all critical connections, i.e., VIN to S1, S1 to D2, and S2 to GND, are made by direct connection to the lead frame or by wide connector 870. These connections introduce minimal parasitic inductance. The device 804, in which only the low side transistor switch has a backside source electrode, exhibits a larger footprint than the packages of FIGS. 11 and 12. A device structure with the low side switch having a source down configuration can provide excellent performance by providing a lower Qrr during commutation of the internal diode.

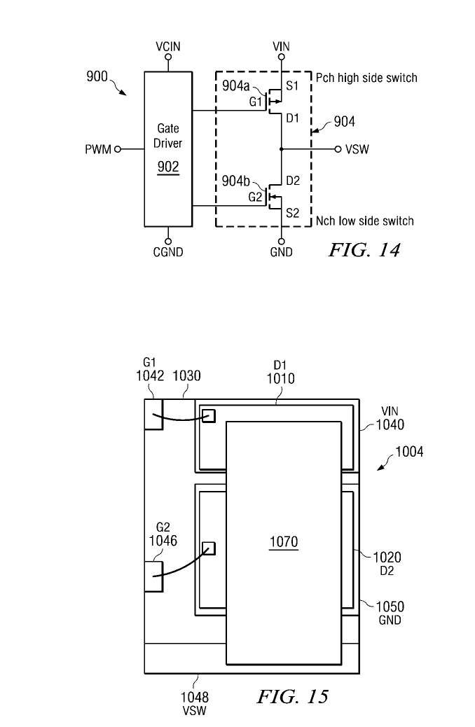

FIG. 14 illustrates an embodiment of a portion of a power converter device 900. The device 900 includes a gate driver 902 and a pair of power transistors 904 arranged in a totem pole configuration having a high side device 904a and a low side device 904b. The device 900 is the same in all respects as the device 500 of FIG. 10 except that the high side device 904a is a p-channel transistor device. As such, the drains of the transistors 904a, 904b are coupled together at switched output node VSW.

Using a p-channel transistor for the high side switch 904a simplifies the driving scheme of the push-pull stage. In low voltage applications, the gate of the high side p-channel device can be driven from rail-to-rail and does not require a charge pump or bootstrap circuit as may be required for n-channel transistor device in low voltage applications. As shown in FIG. 14, the drain electrode D1 of the high side switch 904a is coupled to the drain electrode D2 of the low side switch 904b to provide the switched output node VSW. In the embodiment illustrated in FIG. 15 of a push-pull stage 1004, this drain-to-drain connection can be easily made if both devices have source electrodes at the backside of the die.

With more specific reference to FIG. 15, the packaged push-pull device 1004 includes a p-channel transistor die 1010 with a source terminal S1 at a backside of the die and a drain terminal D1 at a topside of the die packaged within packaging/molding material 1003. The die 1010 is mounted on wide upper voltage lead portion 1040 (labeled VIN), thereby directly coupling source S1 to the leadframe. Likewise, n-channel transistor die 1020 has a source terminal S2 at a backside of the die and a drain terminal D2 at a topside of the die. The die 1020 is mounted on a wide low voltage line lead portion 1020 (labeled GND), directly coupling source S2 to the leadframe. A wide, low inductance conductor 1070 couples the drain terminals D1, D2 together and to the switched output lead portion 1048 (labeled VSW). The cross-sectional view of the device 1004 is essentially identical to device 804 illustrated in FIG. 13A. FIG. 15 also illustrates wirebond connections between gate lead portion 1042 (labeled G1) and the gate of die 1010 and between gate lead portion 1046 (labeled G2) and the gate of die 1020.

As can be seen from the drawings, critical connections, i.e., VIN to S1, D1 to D2, and S2 to GND, are made by direct connection to the lead frame or by wide connector 1070. These connections introduce minimal parasitic inductance.

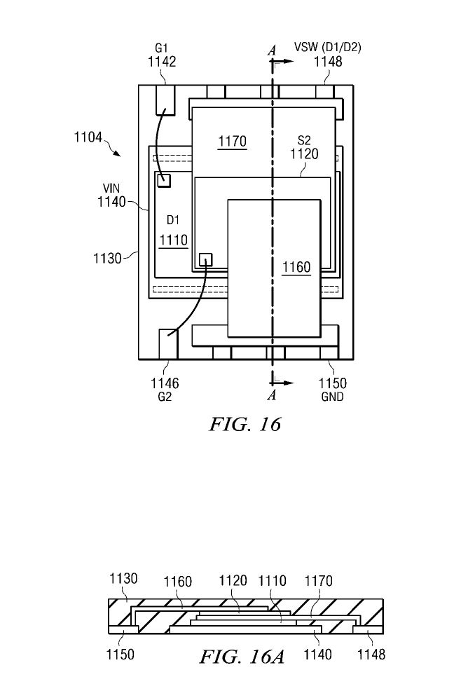

FIG. 16 illustrates an embodiment of packaged semiconductor device 1104 having a p-channel high side switching device 1110 with source S1 at a backside thereof and a n-channel low side switching device 1120 with a drain D2 at a backside thereof. The dies 1110, 1120 are coupled to a leadframe and packaged within packaging/molding material 1130. In this embodiment, the dies 1110, 1120 are disposed in a stacked arrangement, as illustrated in the cross-sectional view of FIG. 16A. High side transistor die 1110 is mounted with its source S1 on wide high voltage line lead portion 1148 (labeled VIN). The drain D1 of the die 1110 is coupled to the switched output lead portion 1148 (labeled VSW (D1/D2)) by wide, low inductance connector 1170. Die 1120 is mounted on the top surface of the connector 1170, with its drain D2 coupled to the connector 1170. As with the other embodiments, the switched node connector 1170 is preferably a copper plate and both high side and low side transistors are soldered to it. As such, the drain terminal D1, D2 and switched out VSW lead are coupled together via a low inductance current path through connector 1170. The source S2 of low side switch die 1120 is coupled to the ground lead portion 1150 (labeled GND) by another low inductance, wide connector 1160. The lead frame of the packaged device 1104 also includes gate lead portion 1142 (labeled G1) wire bonded to the gate terminal of die 1110 and gate lead portion 1146 (labeled G2) wire bonded to the gate terminal of die 1120.

As with the device 1004, all critical connections, i.e., VIN to S1, D1 to D2, and S2 to GND, are made by direct connection to the lead frame or by wide connector 1070. These connections introduce minimal parasitic inductance.

As discussed above and shown in the drawings, the various illustrated embodiments focus on the integration and packaging of two MOSFET transistor dies coupled in a push-pull/totem pole configuration into one power module which exhibits low parasitic inductance at critical connections in the current path through the push-pull/totem pole configuration. Critical connections are made either by wide connectors or by direct connections of the dies to each other or to the lead frame. Using one or more devices with vertical current flow and a backside source terminal/electrode facilitates formation of these low inductance connections. As will be recognized by people skilled in the art, the packaging and connection structures and methods shown herein can be used to integrate multiple high side and low side dies in parallel, and/or to integrate a gate driver IC into the same module.

It should also be understood that FIGS. 11-13 and 15-16 illustrate only a few possible examples of forming low inductance current paths through a packaged push-pull arrangement using at least one device having vertical current flow and a backside source terminal, and other arrangements using different configurations of die-to-die connections, die-to-leadframe connections, and conductive connector combinations and connections are contemplated and fall within the scope of the present invention. By way of example only, the type of stacked die arrangement illustrated in FIG. 16 where the clip connector 1170 is disposed between the high side and low side dies could be employed, for example, in the stacked die arrangement illustrated in FIG. 11 for ground connector 670, if desired.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A packaged switching device for power applications, comprising:
at least one pair of power MOSFET transistor dies connected between upper and lower power source rail leads, a high side one of the pair of MOSFET transistor dies being connected to the upper power source rail lead and a low side one of the pair of MOSFET transistor dies being connected to the lower power source rail lead, wherein at least one of the MOSFET transistor dies is configured for vertical current flow therethrough and has a source electrode at a backside thereof.

2. The packaged switching device of claim 1, wherein both the high side and low side MOSFET transistor dies are n-channel devices.

3. The packaged switching device of claim 2, wherein both the high side and low side MOSFET transistor dies have vertical current flow therethrough and a source electrode at the backside thereof.

4. The packaged switching device of claim 3, wherein the MOSFET transistor dies are stacked one on top of the other with a source electrode of the high side MOSFET transistor die facing a drain electrode of the low side MOSFET transistor die.

5. The packaged switching device of claim 4,
wherein a drain electrode of the high side MOSFET transistor die is coupled to the upper power source rail lead by a conductive clip, and
wherein the drain electrode of the low side MOSFET transistor die is coupled to a switched output lead by a conductive clip.

6. The packaged switching device of claim 2, wherein one of the pair of MOSFET transistor dies has a source electrode at a backside thereof and the other one of the pair of MOSFET transistor dies has a drain electrode at a backside thereof.

7. The packaged switching device of claim 6, wherein the high side MOSFET transistor die has its source electrode at the backside thereof and the low side MOSFET transistor die has its drain electrode at the backside thereof.

8. The packaged switching device of claim 7,
wherein a drain electrode of the high side MOSFET transistor die is coupled to the upper power source rail lead by a conductive clip,
wherein a source electrode of the low side MOSFET transistor die is coupled to the lower power source rail lead by a conductive clip, and
wherein the source electrode of the high side MOSFET transistor die and the drain electrode of the low side MOSFET transistor die are electrically coupled together by being mounted on a switched output lead portion of a leadframe.

9. The packaged switching device of claim 6, wherein the low side MOSFET transistor die has its source electrode at the backside thereof and the high side MOSFET transistor die has its drain electrode at the back side thereof.

10. The packaged switching device of claim 9,
wherein a source electrode of the high side MOSFET transistor die and a drain electrode of the low side MOSFET transistor die are electrically coupled together, and to an output lead, by a conductive clip,
wherein the drain electrode of the high side MOSFET transistor die is mounted on the upper power source rail lead, and
wherein the source electrode of the low side MOSFET transistor die is mounted on the lower power source rail lead.

11. The packaged switching device of claim 1 wherein one of the pair of MOSFET transistor dies is an n-channel device and the other one of the pair of MOSFET transistor dies is a p-channel device, wherein drain electrodes of the MOSFET transistor dies are coupled together.

12. The packaged switching device of claim 1, wherein the high side MOSFET transistor die is a p-channel device and the low side MOSFET transistor die is an n-channel device, wherein drain electrodes of the MOSFET transistor dies are coupled together.

13. The packaged switching device of claim 12, wherein both the high side and low side MOSFET transistor dies have a source electrode at the backside thereof.

14. The packaged switching device of claim 13,
wherein the drain electrodes of the high side MOSFET transistor die and the low side MOSFET transistor die are electrically coupled together, and to an output lead, by a conductive clip,
wherein the source electrode of the high side MOSFET transistor die is mounted on the upper power source rail lead, and
wherein the source electrode of the low side MOSFET transistor die is mounted on the lower power source rail lead.

15. The packaged switching device of claim 12, wherein the drain electrode of the low side MOSFET transistor die is at a backside thereof and a source electrode of the high side MOSFET transistor die is at a backside thereof.

16. The packaged switching device of claim 15, wherein the MOSFET transistor dies are stacked one on top of the other with drain electrodes facing each other.

17. The packaged switching device of claim 16,
wherein a source electrode of the low side MOSFET transistor die is coupled to the lower power source rail lead by a conductive clip,
wherein the drain electrodes of the low side and high side MOSFET transistor dies are coupled to one another, and to an output lead, by a conductive clip, and
wherein the source electrode of the high side die is mounted on the upper power source rail lead.

18. The packaged switching device of claim 1, wherein the at least one MOSFET transistor die configured for vertical current flow therethrough and having its source electrode at the backside thereof is a LDMOS transistor device.

19. The packaged switching device of claim 1, wherein the MOSFET transistor dies are stacked one on top of the other.

20. A packaged switching device for power applications, comprising:
a leadframe having a plurality of lead frame portions for making electrical connections to packaged devices; and
at least one pair of power transistor dies having vertical current flow connected between upper and lower power source rail leads of said lead frame, a high side one of the pair of transistor dies being connected to the upper power source rail lead portion of said lead frame and a low side one of the pair of transistor dies being connected to the lower power source rail lead portion of the lead frame, the transistor dies being electrically coupled together at a switched output lead portion of the lead frame,
wherein each of the following connections is formed through either direct mounting of one of said dies on said lead frame, through direct connection of the dies in a stack or through a low inductance conductive clip connector: (i) upper power source rail lead portion to high side transistor die; (ii) high side transistor die to low side transistor die; and (iii) low side transistor die to lower power source rail lead portion.

21. The packaged switching device of claim 20, wherein the transistor dies are LDMOS transistor dies, at least one of the LDMOS transistor dies having a source electrode at a backside thereof and drain and gate electrodes at a top side thereof.

22. The packaged switching device of claim 20, wherein the dies are stacked one on top of the other.

23. The packaged switching device of claim 20, wherein a connection between the high or low side transistor die to the switched output lead portion is also formed through either direct mounting of one of said dies on said lead frame or through a low inductance conductive clip connector.

24. A power converter for DC-to-DC voltage conversion, comprising:
control and driving circuitry; and
a packaged switching device coupled to said control and driving circuitry, wherein the packaged switching device comprises:
at least one pair of power LDMOS transistor dies configured for vertical current flow therethrough;
a lead frame for making connections to said dies; and
a molding material encapsulating said lead frame and dies,
wherein the dies are connected in a push-pull configuration between upper and lower power source lead portions of the lead frame, a high side one of the pair LDMOS transistor dies being connected to the upper power source rail lead portion and a low side one of the pair of MOSFET transistor dies being connected to the lower power source rail lead portion, wherein at least one of the dies has a source electrode at a backside thereof.
